(19) United States
(12) Patent Application Publication
(10) Pub. No.: US 2013/0267083 A1
(43) Pub. Date: Oct. 10, 2013

(54) PRODUCING METHOD FOR SEMICONDUCTOR DEVICE

(71) Applicant: KABUSHIKI KAISHA TOSHIBA, Tokyo (JP)

(72) Inventor: Kyoichi Suguro, Yokohama-shi (JP)

(21) Appl. No.: 13/908,538

(22) Filed: Jun. 3, 2013

Related U.S. Application Data
(63) Continuation of application No. PCT/JP2011/071755, filed on Sep. 15, 2011.

(30) Foreign Application Priority Data
Dec. 3, 2010 (JP) 2010-270654

(51) Int. Cl. H01L 21/265

(52) U.S. Cl. CPC H01L 21/2658
USPC 438/527

(57) ABSTRACT

According to one embodiment, a producing method for a semiconductor device includes first impurities containing phosphorus or boron in the form of molecular ion and second impurities containing carbon, fluorine or nitrogen with less implantation amount than this phosphorus or boron in the form of molecular ion are implanted into a semiconductor layer to form an impurity implantation layer.

### CROSS-REFERENCE TO RELATED APPLICATION

This application is based upon and claims the benefit of priority from prior Japanese Patent Application No. 2010-270654, filed on Dec. 3, 2010, the entire contents of which are incorporated herein by reference.

### FIELD

Embodiments of the present invention relate to a producing method for a semiconductor device.

### BACKGROUND

A producing method for a semiconductor device, such as to implant impurities for preventing conductive impurities implanted into a substrate from diffusing unnecessarily, is known as a prior art.

According to a conventional producing method for a semiconductor device, conductive impurities are restrained from diffusing by impurities, so that a diffusion layer may be formed in a narrow region. However, in a conventional producing method for a semiconductor device, a diffusion layer is formed in a narrower region for further micronization, so that crystal recovery by heat treatment is not sufficiently performed and the problem is that leak current occurs resulting from a crystal defect such as a dislocation defect.

### BRIEF DESCRIPTION OF THE DRAWINGS

FIGS. 1A to 1D are principal part cross-sectional views showing production processes of a semiconductor device according to a first embodiment.

FIGS. 2A and 2B are principal part cross-sectional views showing production processes of a semiconductor device according to a second embodiment.

FIGS. 3A and 3B are principal part cross-sectional views showing production processes of a semiconductor device according to a third embodiment.

FIGS. 4A and 4B are principal part cross-sectional views showing production processes of a semiconductor device according to a fourth embodiment.

FIGS. 5A to 5G are principal part cross-sectional views showing production processes of a semiconductor device according to a fifth embodiment.

FIGS. 6A to 6F are principal part cross-sectional views showing production processes of a semiconductor device according to a sixth embodiment.

FIG. 7 is a graph of carbon concentration, contact resistivity and leak current.

FIG. 8 is a graph of fluorine concentration, contact resistivity and leak current.

FIG. 9 is a graph of nitrogen concentration, contact resistivity and leak current.

### DETAILED DESCRIPTION

In one embodiment, a producing method for a semiconductor device includes forming an impurity implantation layer by implanting into a semiconductor layer first impurities containing phosphorus or boron in the form of molecular ion and second impurities containing carbon, fluorine or nitrogen with less implantation amount than the above-mentioned phosphorus or boron in the form of molecular ion.

### First Embodiment

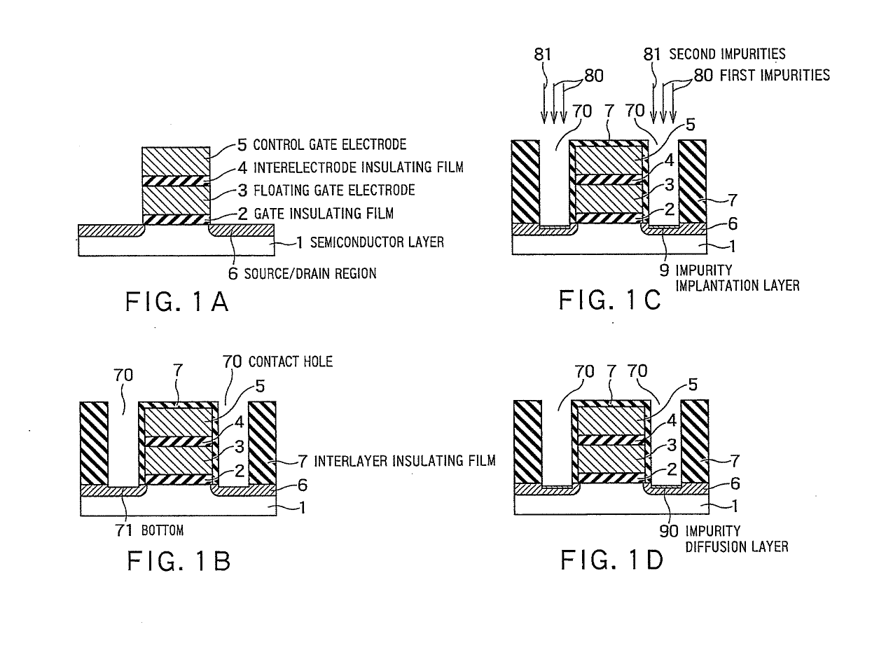

FIGS. 1A to 1D are principal part cross-sectional views showing production processes of a semiconductor device according to a first embodiment. For example, a process of forming a two-layer electrode-type transistor is described hereinafter. This two-layer electrode-type transistor is a cell transistor composing a memory as a semiconductor device.

### (Producing Method for Semiconductor Device)

First, as shown in FIG. 1A, a gate insulating film 2, a floating gate electrode 3, an interelectrode insulating film 4 and a control gate electrode 5 are sequentially formed on a semiconductor layer 1.

For example, the semiconductor layer 1 is formed by using silicon as the main element and provided with p-type or n-type electrical conductivity in accordance with the conductive type of a transistor to be formed. In this semiconductor layer 1, a source-drain region 6, which was formed by implanting n-type impurities if the semiconductor layer 1 is of p-type or implanting p-type impurities if the semiconductor layer 1 is of n-type, is formed in the neighborhood of a surface thereof.

For example, the gate insulating film 2 is formed by using a silicon oxide film, a hafnium-based oxide film (such as HfO₂) or a silicon oxynitride film (such as HfSiON). The gate insulating film 2 in the present embodiment is a silicon oxide film, for example, and formed by a thermal oxidation method.

For example, the floating gate electrode 3 and the control gate electrode 5 are formed by using polysilicon and formed by a CVD (Chemical Vapor Deposition) method.

For example, the interelectrode insulating film 4 is an ONO (Oxide Nitride Oxide) film. The interelectrode insulating film 4 includes, for example, a silicon oxide film, a silicon nitride film formed on this silicon oxide film, and a silicon oxide film formed on this silicon nitride film. The silicon oxide film is formed by a thermal oxidation method, for example. The silicon nitride film is formed by a CVD method, for example.

Next, as shown in FIG. 1B, an interlayer insulating film 7 is formed on the semiconductor layer 1 by a CVD method. This interlayer insulating film 7 is formed by using a silicon oxide film, for example. This interlayer insulating film 7 has plural contact holes 70 formed by using an RIE (Reactive Ion Etching) method, for example. The after-mentioned impurity diffusion layer is formed at the bottom 71 of this contact hole 70.

Next, as shown in FIG. 1C, first and second impurities 80 and 81 are implanted by an ion implantation method into the source-drain region 6 of the semiconductor layer 1 exposed to the contact hole 70 to form an impurity implantation layer 9.

When the conductive type of a transistor to be formed is of n-type, the electrical conductivity of the source-drain region 6 is of n-type. When the conductive type of a transistor is of n-type, the first impurities 80 contain phosphorus in the form of molecular ion. That is to say, the first impurities 80 contain at least one kind of molecular ion which satisfies Pa (a is an integer of 2 or more), for example.

On the other hand, when the conductive type of a transistor is of p-type, the electrical conductivity of the source-drain region 6 is of p-type. When the conductive type of a transistor is of p-type, the first impurities 80 contain boron in the form of molecular ion. That is to say, the first impurities 80 contain at least one kind of molecular ion which satisfies BbHc (b is an integer of 2 or more and c is an integer of 6 or more), for example.

The second impurities 81 contain carbon, fluorine or nitrogen with less implantation amount than the first impurities 80 as a molecular ion, for example. The second impurities 81 according to the present embodiment contain at least one kind of molecular ion which satisfies CdHe (d is an integer of 2 or more and e is an integer of 6 or more), for example. In the case where the second impurities 81 contain fluorine, F₂ or PF₃ are used as a molecular ion, for example; in the case of containing nitrogen, N₂ or NH₃ are used.

The second impurities 81 are preferably impurities such that contact resistivity and leak current rise with difficulty even though the impurity concentration of the second impurities 81 is raised; therefore, impurities containing carbon are most preferable and impurities containing fluorine are secondly preferable. However, in the case where fluorine concentration exceeds 1E20 cm⁻³, leak current becomes so large that it is not preferable that impurities containing fluorine are used as the second impurities 81 in a semiconductor device which is strict in the conditions with regard to leak current.

The formation of the impurity implantation layer 9 as an n+ layer is performed by using P₂ or P₄ as the first impurities 80 and C₇H₇, C₁₂H₁₂ or C₁₄H₁₄ as the second impurities 81 in a dilution gas atmosphere of helium or hydrogen, for example. Ion implantation is preferably performed in order of ion-implanting the second impurities 81 before ion-implanting the first impurities 80. The performance of ion implantation in this order may restrain channeling in ion-implanting p-type or n-type impurities as compared with the case of ion-implanting simultaneously or in contrary order, so that a steeper impurity atomic distribution of p-type or n-type may be realized.

For details, in the case of performing ion implantation on the conditions of implanting the second impurities 81 more deeply than the first impurities 80, the order of implanting the first impurities 80 and the second impurities 81 is not limited. In the case of implanting the first impurities 80 and the second impurities 81 to the same depth, as described above, the second impurities 81 are preferably ion-implanted before ion-implanting the first impurities 80. In this case, a damage layer (a crystal defect layer) is formed in the source-drain region 6 by implanting the second impurities 81, and an orbit of the first impurities 80 in the source-drain region 6 in implanting the first impurities 80 is disordered by the presence of the damage layer; that is, channeling is restrained and the first impurities 80 are restrained from diffusing. Accordingly, a steeper distribution of the first impurities 80 may be realized.

For example, carbon in an atomic ion may be used for the second impurities 81. On this occasion, the implantation of the impurities is performed while cooling the semiconductor layer 1 to 0° C. or less (desirably, −50° C. or less). Silicon during ion implantation is restrained from recrystallizing by ion-implanting at low temperature, so that an interface between an ion implantation layer and a Si monocrystalline substrate is flattened.

On the other hand, the formation of the impurity implantation layer 9 as a p+ layer is performed by using B₁₀H₁₄, B₁₈H₂₂, B₂₀H₂₈ or B₃₆H₄₄ as the first impurities 80 and C₇H₇, C₁₂H₁₂ or C₁₄H₁₄ as the second impurities 81 in a dilution gas atmosphere of helium or hydrogen, for example. In the case where the second impurities 81 contain fluorine, F₂ or PF₃ are used as a molecular ion, for example; in the case of containing nitrogen, N₂ or NH₃ are used.

Here, phosphorus is low in crystal defect density by implantation as compared with arsenic which allows the same electrical conductivity to an object, but has the problem of diffusing extensively by heat treatment. Meanwhile, boron is low in crystal defect density by implantation as compared with boron fluoride which allows the same electrical conductivity to an object, but has the problem of diffusing extensively by heat treatment. Carbon, fluorine and nitrogen are implanted for the purpose of restraining unnecessary diffusion of phosphorus and boron by heat treatment by reason of bonding to silicon of the semiconductor layer 1 to hinder diffusion of phosphorus and boron.

The conditions of implanting impurities in forming the impurity implantation layer 9 are an acceleration energy of 10 to 30 KeV and a dosage of 2 to 5×10¹⁵ cm⁻², for example.

Next, as shown in FIG. 1D, the implanted first impurities 80 are activated by heat treatment at a temperature of 1000° C. or less to form an impurity diffusion layer 90. Specifically, this heat treatment is performed at a temperature of 950 to 980° C. for 30 seconds or less. This impurity diffusion layer 90 decreases contact resistance to a contact plug formed in the contact hole 70. A cell transistor has a high possibility that a malfunction occurs due to heat treatment at a high temperature more than 1000° C. However, in a producing method for a semiconductor device according to the present embodiment, crystal defects are so few as to be capable of activating at low temperature and improve the yield.

The above-mentioned heat treatment may be also performed by a heating method with the use of an electromagnetic wave in an inert gas atmosphere or an atmosphere including oxygen by 10% or less. On this occasion, it is preferable that the semiconductor layer 1 is kept at a temperature of 300° C. or more and heat treatment is performed for 10 minutes or less.

Next, a desired semiconductor device is obtained through known processes.

According to the first embodiment, as compared with the case of not implanting phosphorus or boron in the form of molecular ion and carbon, fluorine or nitrogen in the form of molecular ion, ion-implanted phosphorus or boron may be restrained from diffusing to decrease a crystal defect.

For details, according to the first embodiment, the first impurities 80 may be restrained from diffusing by implanting the second impurities 81. In addition, the amorphous impurity implantation layer 9 may be formed more uniformly in the source-drain region 6 by implanting these impurities in the form of molecular ion, so that an interface between the impurity implantation layer 9 and the source-drain region 6 as a silicon monocrystal may be flattened. Then, during heat treatment to be performed thereafter, the interface is so flat that a crystal defect and a crystal dislocation may be restrained from occurring in the neighborhood of this interface.

On the other hand, in the case of implanting the first impurities 80 in the form of an atomic ion, the impurity implantation layer 9 is recrystallized so immediately after implanting that the impurity implantation layer 9 maintains an amorphous form with difficulty, that is, the interface between the impurity implantation layer 9 and the source-drain region 6 maintains flatness with difficulty. Accordingly, a crystal defect and a crystal dislocation in the neighborhood of this interface occasionally occur during heat treatment.

Even in the case of using a molecular ion as the second impurities 81, ion implantation may be performed while cooling the semiconductor layer 1 to 0° C. or less (desirably, −50° C. or less) in the same manner as ion implantation in the case of using carbon in the form of an atomic ion as the second impurities 81.

When ion implantation is performed for the semiconductor layer 1 without cooling as described above, ion beam anneal is caused in accordance with the occurrence of a crystal defect; additionally, recrystallization is caused by this ion beam anneal to occasionally form irregularities on the interface between the impurity implantation layer 9 and the source-drain region 6. When heating at high temperature is performed in such a state, interstitial atoms gathers around the interface and dislocations are easily formed. On the other hand, when ion implantation is performed while cooling as described above, ion beam anneal is caused with such difficulty that recrystallization is caused with difficulty to be capable of improving flatness of the interface between the impurity implantation layer 9 and the source-drain region 6. Then, during the treatment to be performed thereafter, a crystal defect and a crystal dislocation may be further restrained from occurring in the neighborhood of this interface.

### Second Embodiment

A second embodiment is different from the first embodiment in implanting impurities into a narrow region surrounded by an element isolation region. In each of the following embodiments, the same reference numerals as the first embodiment are provided for portions having the same constitution and function as the first embodiment, and the description thereof will not be repeated.

### (Producing Method for Semiconductor Device)

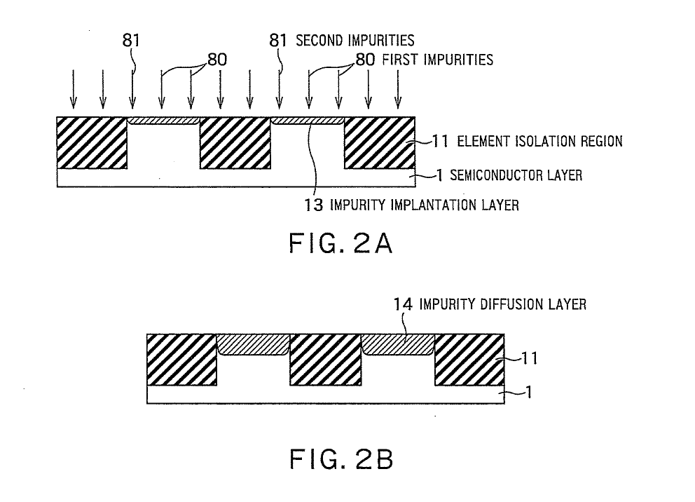

FIGS. 2A and 2B are principal part cross-sectional views showing production processes of a semiconductor device according to the second embodiment.

First, an element isolation region 11 is formed in a semiconductor layer 1 by known processes. This element isolation region 11 is formed by using a silicon oxide film, for example. An interval between the element isolation regions 11 is 50 nm, for example.

Next, as shown in FIG. 2A, first and second impurities 80 and 81 are implanted by an ion implantation method into the semiconductor layer 1 to form an impurity implantation layer 13.

The conditions of implanting impurities in forming the impurity implantation layer 13 are an acceleration energy of 10 to 30 KeV and a dosage of 2 to 5×10¹⁵ cm⁻², for example.

Next, as shown in FIG. 2B, the implanted first impurities 80 are activated by heat treatment at a temperature of 1000° C. or less to form an impurity diffusion layer 14. Subsequently, a desired semiconductor device is obtained through known processes. Specifically, this heat treatment is performed at a temperature of 950 to 980° C. for 30 seconds or less.

According to the second embodiment, even though surrounded by the element isolation regions 11, first and second impurities 80 and 81 are implanted to perform heat treatment, so that ion-implanted impurities may be restrained from diffusing to form the impurity diffusion layer 14 with few crystal defects. In the case of a metal layer and a metallic oxide layer susceptible to damage due to heat in performing heat treatment after ion implantation, the damage to the materials may be removed to obtain desired device performance.

### Third Embodiment

A third embodiment is different from each of the above-mentioned embodiments in replacing heat treatment with microwave treatment.

### (Producing Method for Semiconductor Device)

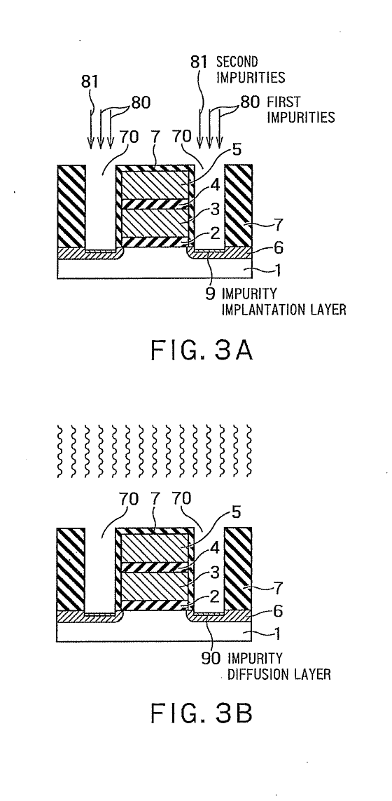

FIGS. 3A and 3B are principal part cross-sectional views showing production processes of a semiconductor device according to the third embodiment. A producing method for a semiconductor device in the embodiment is hereinafter described, and portions different from other embodiments are mainly described.

First, an interlayer insulating film 7 is formed on a semiconductor layer 1 by performing the processes of FIGS. 1A and 1B in the first embodiment.

Next, as shown in FIG. 3A, first and second impurities 80 and 81 are implanted by an ion implantation method into a source-drain region 6 of the semiconductor layer 1 exposed to a contact hole 70 to form an impurity implantation layer 9.

Next, as shown in FIG. 3B, the first impurities 80 are activated by performing microwave treatment in an inert gas atmosphere or an atmosphere including oxygen by 10% or less to form an impurity diffusion layer 90. Subsequently, a desired semiconductor device is obtained through known processes.

Specifically, the implanted first impurities 80 are activated by microwave treatment to form the impurity diffusion layer 90. This microwave is preferably a microwave with a frequency higher than 2.45 GHz and lower than 50 GHz, more preferably a microwave with a frequency of 5.8 GHz to 30 GHz. A frequency band centering around 5.80 GHz is designated to ISM (Industry-Science-Medical) band, so that a magnetron is easily available.

It is desirable that the power density of the microwave to be used is determined so as to become 2.1 W to 3.6 W per 1 cm² and the microwave is irradiated for approximately 1 minute to 10 minutes. In addition, microwave treatment is desirably performed so as to keep the semiconductor layer 1 at 500° C. or less, desirably 300° C. or less, and cooling is performed as required. Cooling may restrain the temperature of the semiconductor layer 1 from rising and may further raise the irradiation power of the microwave to further draw out the effect by microwave treatment, so that the first impurities 80 may be activated easily. Accordingly, the embodiment is performed at lower temperature as compared with the embodiments described so far. Examples of a cooling method include a method for running inert gas on the back surface of the semiconductor layer 1.

The temperature of the semiconductor layer 1 is measured by using a pyrometer through a glass fiber from the backside of the semiconductor layer 1. For details, the temperature at the central portion of the back surface of the semiconductor layer 1 or a region, such as, within 30 mm from the center thereof is measured. In the case of requiring accurate temperature measurement for process control, plural regions, such as the central portion, the outer circumference of the back surface of the semiconductor layer 1 and the intermediate portion of the central portion and the outer circumference are measured.

In addition, in order to prevent anomalous discharge in the process chamber, the pressure in the process chamber is preferably approximated to 1 atm.

According to the third embodiment, as compared with the case of not using microwave treatment, the first impurities 80 may be activated at so low temperature as to form the impurity diffusion layer 90 and restrain unnecessary diffusion of the first impurities 80. That is to say, the microwave may efficiently lead to a necessary spot by reason of being long in wavelength as compared with infrared rays and high in permeability into a crystal. Accordingly, while avoiding raising the temperature of the semiconductor layer 1, the first impurities 80 may be activated to form the impurity diffusion layer 90. Therefore, the impurity diffusion layer 90 may be formed at so low temperature as to restrain unnecessary diffusion of the first impurities 80.

That is, the present embodiment utilizes the characteristics of the microwave. The characteristics of the microwave are hereinafter described.

The microwave generally signifies an electromagnetic wave with a frequency of 300 MHz to 300 GHz; accordingly, in the microwave, an electric field and a magnetic field exist so as to become perpendicular to each other against the traveling direction of the wave. Then, these electric field and magnetic field become the maximum where the wave becomes the maximum amplitude, and become zero the moment the amplitude of the wave becomes zero.

Incidentally, when impurities and crystal defects (atomic vacancy, interstitial atom and unbound atom) exist in a silicon crystal, electric charge distribution occurs in the silicon crystal. In particular, the impurities cause an impurity atom and a silicon atom to differ in electronegativity, so that an electron is biased toward an atom which attracts an electron easily (negatively charged) while another atom becomes in a state of being short of an electron (positively charged). Thus, an electric dipole is formed in the silicon crystal. Then, when the microwave is irradiated, this electric dipole vibrates in accordance with the electric field of the microwave. Therefore, this vibration becomes larger as the power of the microwave becomes larger.

In addition, the characteristics of the microwave are further described while compared with infrared rays used in heat treatment such as RTA (Rapid Thermal Annealing) and furnace anneal.

With regard to infrared rays, the wavelength thereof is so short as 10 μm and is so high as 30 THz in terms of frequency that the irradiation of infrared rays on the silicon crystal causes stretching vibration of the bonding between the adjacent silicon atoms in the silicon crystal and causes torsional vibration (rotation vibration) of the bonding between the silicon atoms with difficulty. In such stretching vibration, the position of the silicon atoms does not move largely, so that rearrangement of the bonding between the silicon atoms is caused with difficulty.

On the other hand, in the case of irradiating the microwave on the silicon crystal, rearrangement of the bonding between the silicon atoms is caused efficiently for the reason that the bonding of four Sp³ hybrid orbitals between the silicon atoms vibrates so as to be distorted. The microwave is long in wavelength as compared with infrared rays and high in permeability into the silicon crystal. Accordingly, the microwave leads to a necessary spot efficiently.

However, even in the microwave, 2.45 GHz as the frequency of a domestic microwave oven is so low that torsional vibration of the bonding between the silicon atoms is efficiently caused with difficulty. On the other hand, when the frequency exceeds 30 GHz, torsional vibration of the bonding between the silicon atoms may not begin to follow. Accordingly, when the frequency is in an intermediate region of these frequencies, such as 5.8 GHz, torsional vibration of the bonding between the silicon atoms is caused efficiently and rearrangement of the silicon atoms is easily caused efficiently.

Thus, microwave treatment is different treatment from heat treatment and torsional vibration of the bonding between the silicon atoms may be caused without heating to high temperature, so that a change in position of the atoms, namely, rearrangement of the bonding is caused so easily that the first impurities 80 may be activated with high efficiency while restraining unnecessary diffusion. In particular, in the case of using a molecular ion as the first impurities 80, in an impurity implantation layer 9, crystal defect density is so high and asymmetry of electron distribution is so large due to the introduction of the first impurities 80 that polarization becomes large. Accordingly, the performance of microwave irradiation allows torsional vibration to be easily caused, and the activation and crystal defect recovery effect of the first impurities 80 are large.

Similarly to the first embodiment, even in the case of using carbon in the form of an atomic ion as the second impurities 81, microwave treatment of the embodiment may be applied.

### Fourth Embodiment

A fourth embodiment is different from each embodiment in implanting impurities into a narrow region surrounded by an element isolation region and performing microwave treatment.

### (Producing Method for Semiconductor Device)

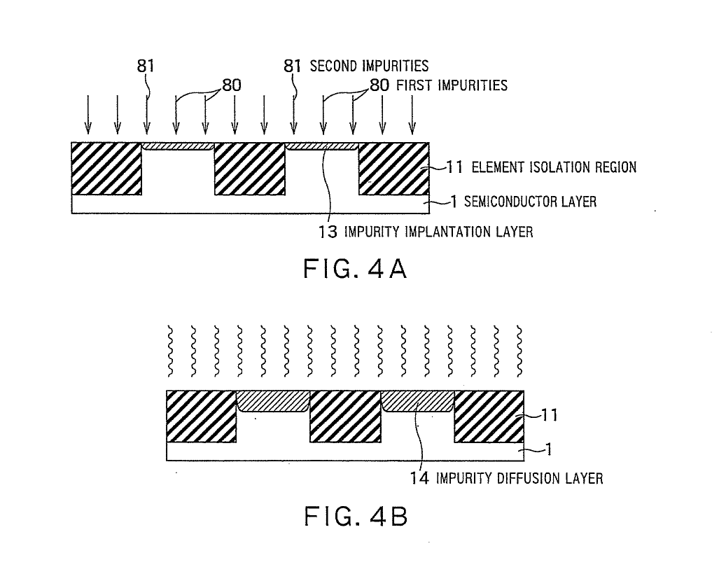

FIGS. 4A and 4B are principal part cross-sectional views showing production processes of a semiconductor device according to the fourth embodiment.

First, an element isolation region 11 is formed in a semiconductor layer 1 by known processes.

Next, as shown in FIG. 4A, first and second impurities 80 and 81 are implanted by an ion implantation method into the semiconductor layer 1 to form an impurity implantation layer 13.

Next, as shown in FIG. 4B, the first impurities 80 are activated by performing microwave treatment in an inert gas atmosphere or an atmosphere including oxygen by 10% or less to form an impurity diffusion layer 14. Subsequently, a desired semiconductor device is obtained through known processes.

Specifically, the implanted first impurities 80 are activated by microwave treatment to form the impurity diffusion layer 14. This microwave treatment is preferably a microwave with a frequency higher than 2.45 GHz and lower than 50 GHz, more preferably a microwave with a frequency of 5.8 GHz to 30 GHz.

It is desirable that the power density of the microwave to be used is determined so as to become 2.1 W to 3.6 W per 1 cm² and the microwave is irradiated for approximately 1 minute to 10 minutes. In addition, microwave treatment is desirably performed so as to keep the semiconductor layer 1 at 500° C. or less, desirably 300° C. or less, and cooling is performed as required.

In addition, in order to prevent anomalous discharge in a process chamber, the pressure in the process chamber is preferably approximated to 1 atm.

According to the fourth embodiment, even though surrounded by the element isolation regions 11, the first impurities 80 may be activated at so low temperature by microwave treatment as to form the impurity diffusion layer 14 and form an impurity diffusion layer 14 with few crystal defects.

### Fifth Embodiment

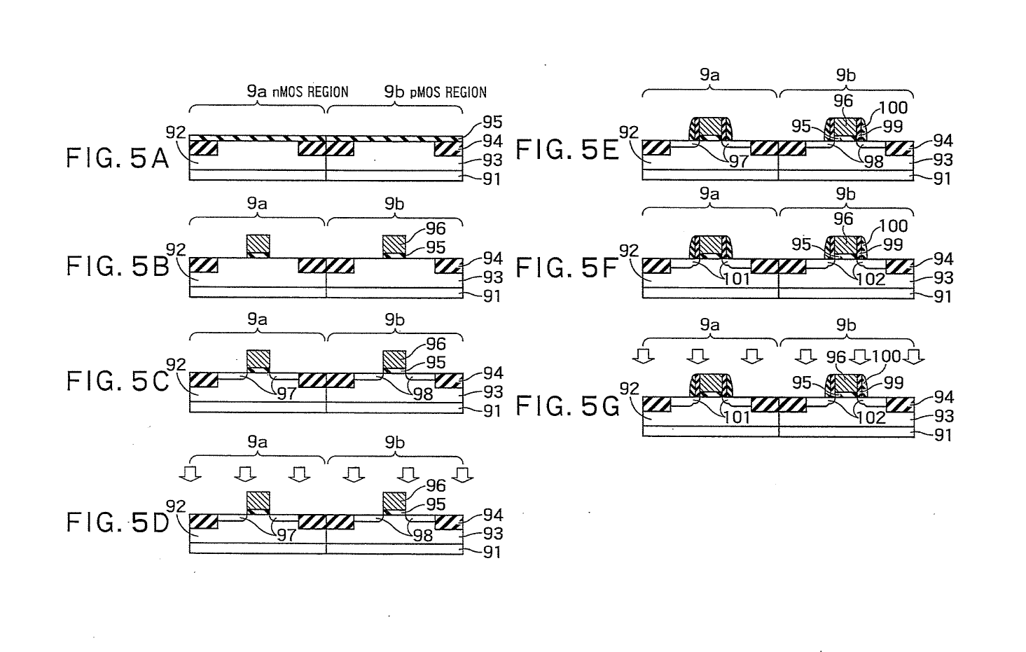

FIGS. 5A to 5G are principal part cross-sectional views showing production processes of a semiconductor device according to a fifth embodiment. In the present embodiment, a producing method for a CMOS (Complementary Metal Oxide Semiconductor) transistor as a semiconductor device is described. The case of forming an n-type transistor in an nMOS region 9a and a p-type transistor in a pMOS region 9b shown in FIG. 5A is hereinafter described.

### (Producing Method for Semiconductor Device)

First, as shown in FIG. 5A, a p-type well 92 and an n-type well 93 as a semiconductor layer and an element isolation insulating film 94 are formed on a p-type substrate 91 having as the main component silicon doped with boron at approximately an acceleration energy of 10 to 30 KeV and a dosage of 2×10¹⁵ cm⁻² to thereafter form a gate insulating film 95.

The p-type well 92 is formed in the nMOS region 9a and the n-type well 93 is formed in the pMOS region 9b.

The element isolation insulating film 94 is formed in a boundary between the p-type well 92 and the n-type well 93 by a CVD method, for example. The element isolation insulating film 94 is formed by using a silicon oxide film, for example.

The gate insulating film 95 is formed on the p-type well 92 and the n-type well 93 by a thermal oxidation method, for example. The gate insulating film 95 is formed by using a silicon oxide film, for example.

Next, as shown in FIG. 5B, a gate electrode 96 is formed by a CVD method.

The gate electrode 96 is formed by using polysilicon or amorphous silicon, for example.

Next, as shown in FIG. 5C, a shallow impurity introduction layer 97 such that a molecular ion as first impurities is implanted into the nMOS region 9a and a shallow impurity introduction layer 98 such that a molecular ion as first impurities is implanted into the pMOS region 9b are formed by an ion implantation method.

Specifically, a sidewall insulating film including a silicon oxide film, a silicon nitride film or a lamination layer thereof with a thickness of 10 nm or less is formed by a CVD method to subsequently implant C₇H₇, C₁₂H₁₂ or C₁₄H₁₄ in the form of molecular ion as second impurities to a depth of approximately 10 nm by an ion implantation method so as to become a concentration of 5×10¹⁹ cm⁻³ or more. Subsequently, the pMOS region 9b is masked with a resist pattern to thereafter form the impurity introduction layer 97 while implanting P₂ or P₄ in the form of molecular ion into the nMOS region 9a by an ion implantation method. Subsequently, after removing the resist pattern, the nMOS region 9a is masked with a resist pattern to thereafter form the impurity introduction layer 98 while implanting B₁₀H₁₄, B₁₈H₂₂, B₂₀H₂₈ or B₃₆H₄₄ in the form of molecular ion into the pMOS region 9b by an ion implantation method. The above-mentioned ion implantation of molecular ion is performed by using a plasma doping method in the case of requiring an impurity introduction layer with a depth of 20 nm or less, for example.

This plasma doping method is a method which allows extensive ion implantation in a short time at high concentration, and allows the occurrence of a crystal defect to be further decreased.

Next, as shown in FIG. 5D, electrical activation of the implanted first impurities is performed by heat treatment with a microwave heating method.

Next, as shown in FIG. 5E, a silicon oxide film 99 and a silicon nitride film 100 are formed on the side face of the gate electrode 96.

Specifically, the silicon oxide film is formed on the nMOS region 9a and the pMOS region 9b by a CVD method to expose the element isolation insulating film 94, the impurity introduction layer 97 and the impurity introduction layer 98 by an RIE method. Subsequently, the silicon nitride film is formed on the nMOS region 9a and the pMOS region 9b by a CVD method to expose the element isolation insulating film 94, the impurity introduction layer 97 and the impurity introduction layer 98 by an RIE method, whereby a sidewall having a laminated structure of the silicon oxide film 99 and the silicon nitride film 100 is formed on the side face of the gate electrode 96.

Next, as shown in FIG. 5F, a deep impurity introduction layer 101 such that a molecular ion as first impurities is implanted into the nMOS region 9a and a deep impurity introduction layer 102 such that a molecular ion as first impurities is implanted into the pMOS region 9b are formed by an ion implantation method.

Specifically, C₇H₇, C₁₂H₁₂ or C₁₄H₁₄ in the form of molecular ion as second impurities is implanted into the nMOS region 9a and the pMOS region 9b to a depth of approximately 20 nm by an ion implantation method so as to become a concentration of 1×10²⁰ cm⁻³ or more. Subsequently, the pMOS region 9b is masked with a resist pattern to thereafter form the impurity introduction layer 101 while implanting P₂ or P₄ in the form of molecular ion into the nMOS region 9a by an ion implantation method. Subsequently, after removing the resist pattern, the nMOS region 9a is masked with a resist pattern to thereafter form the impurity introduction layer 102 while implanting B₁₀H₁₄, B₁₈H₂₂, B₂₀H₂₈ or B₃₆H₄₄ in the form of molecular ion into the pMOS region 9b by an ion implantation method. The above-mentioned introduction of molecular ion is performed by using a plasma doping method in the case of requiring an impurity introduction layer with a depth of 20 nm or less, for example.

Next, as shown in FIG. 5G, electrical activation of the implanted first impurities is performed by heat treatment with a microwave heating method to obtain a desired transistor through known processes.

According to the fifth embodiment, a high-performance transistor may be formed such that impurities are restrained from diffusing, the short channel effect is small, and the ratio (Ion/Ioff ratio) of ON-state current to OFF-state current with low parasitic resistance is large.

### Sixth Embodiment

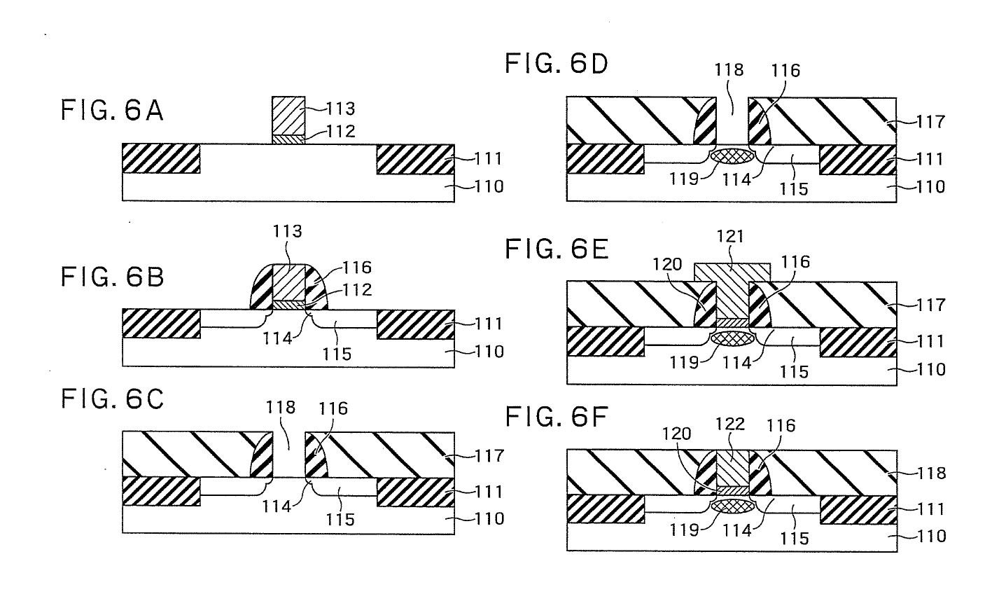

FIGS. 6A to 6F are principal part cross-sectional views showing production processes of a semiconductor device according to a sixth embodiment. A transistor as a semiconductor device according to the present embodiment is produced by a producing method different from the fifth embodiment. The producing method of a semiconductor device is hereinafter described.

### (Producing Method for Semiconductor Device)

First, as shown in FIG. 6A, an element isolation insulating film 111 is formed on a substrate 110 as a semiconductor layer by a CVD method to subsequently form a silicon oxide film 112 and a dummy gate 113 on the substrate 110. This substrate 110 is a substrate having silicon as the main component, for example.

Specifically, a precursor film of the silicon oxide film 112 is formed on the substrate 110 by a thermal oxidation method. Subsequently, a precursor film of the dummy gate 113 is formed on the silicon oxide film 112 by a CVD method to form the silicon oxide film 112 and the dummy gate 113 by a photolithographic method and an RIE method. This dummy gate 113 includes polysilicon or amorphous silicon, for example.

Next, P₂ or P₄ in the form of molecular ion, or B₁₀H₁₄, B₁₈H₂₂, B₂₀H₂₈ or B₃₆H₄₄ in the form of molecular ion as first impurities in accordance with electrical conductivity of a semiconductor device, and impurities containing at least one of carbon, fluorine or nitrogen in the form of molecular ion as second impurities are implanted into a region as a source-drain region by an ion implantation method while using the dummy gate 113 as a mask to form a shallow impurity layer 114 with a thickness of 20 nm or less. This implantation of impurities may be performed by a plasma doping method, for example.

Next, electrical activation of the implanted first impurities is performed by heat treatment with a microwave heating method.

Next, first impurities in accordance with electrical conductivity and impurities containing at least one of carbon, fluorine or nitrogen in the form of molecular ion as second impurities are implanted into a region as a source-drain region by an ion implantation method to form a deep impurity layer 115.

Specifically, the deep impurity layer 115 is formed by implanting B₁₀H₁₄, B₁₈H₂₂, B₂₀H₂₈ or B₃₆H₄₄ in the form of molecular ion as first impurities in the case of producing a p-type transistor, or implanting P₂ or P₄ in the form of molecular ion as first impurities in the case of producing an n-type transistor, for example.

Next, electrical activation of the implanted first impurities is performed by heat treatment with a microwave heating method.

Next, a sidewall 116 is formed on the side face of the dummy gate 113. This sidewall 116 includes a laminated structure of a silicon oxide film, a silicon nitride film, or a silicon oxide film and a silicon nitride film, for example.

Specifically, an insulating film is formed on the substrate 110 by a CVD method to subsequently form the sidewall 116 by removing the insulating film by an RIE method so as to expose the substrate 110 and the element isolation insulating film 111.

Next, an interlayer insulating film 117 is formed on the substrate 110 by a CVD method to expose the dummy gate 113 while flattening by a CMP (Chemical Mechanical Polishing) method.

The interlayer insulating film 117 includes a silicon oxide film or a fluorine-added silicon oxide film (SiOF) with lower permittivity than a silicon oxide film, for example.

Next, as shown in FIG. 6C, an opening 118 is formed in the interlayer insulating film 117 by removing the silicon oxide film 112 under the dummy gate 113 together with the exposed dummy gate 113 by an RIE method.

Next, as shown in FIG. 6D, impurities are implanted into the substrate 110 exposed to the opening 118 while using the interlayer insulating film 117 as a mask by an ion implantation method to form a local channel 119.

Specifically, the local channel 119 is formed in a region for forming a p-type transistor by implanting antimony (Sb) or arsenic at a concentration of 1×10¹⁸ cm⁻³ to 5×10¹⁸ cm⁻³. Meanwhile, the local channel 119 is formed in a region for forming an n-type transistor by implanting indium at a concentration of 1×10¹⁸ cm⁻³ to 5×10¹⁸ cm⁻³.

Next, as shown in FIG. 6E, a gate insulating film 120 is formed at the bottom of the opening 118 by a CVD method to subsequently form a gate electrode material film 121 by a CVD method so as to fill up the opening 118.

The gate insulating film 120 includes a silicon oxynitride film (SiON) or a High-k material with lower permittivity than a silicon oxynitride film, for example. This High-k material includes a hafnium-based oxide film such as a hafnium silicon oxynitride film (HfSiON) and a hafnium oxide film (HfO₂), or a silicon oxynitride film, for example.

Next, as shown in FIG. 6F, a gate electrode 122 is formed by removing the gate electrode material film 121 on the interlayer insulating film 117 by a CMP method to obtain a desired transistor.

According to the sixth embodiment, a high-performance transistor may be formed such that impurities are restrained from diffusing, the short channel effect is small, and the ratio (Ion/Ioff ratio) of ON-state current to OFF-state current with low parasitic resistance is large.

### (Modification)

The ion implantation of phosphorus and carbon or fluorine, or boron and carbon or fluorine may be simultaneously performed as a modification of the above-mentioned embodiments by using a plasma doping method.

Specifically, plasma is formed by using PH₃ in an atmosphere of dilution gas of helium or hydrogen, and plasma is formed by using CH₄ in the case of carbon, or using either F₂ or PF₃ in the case of fluorine to perform simultaneous doping or continuous doping of phosphorus and carbon or fluorine. In the case of using boron, doping is performed by using gas of B₂H₆ diluted with helium or gas of B₂H₆ diluted with hydrogen.

In performing a plasma doping method, the temperature of a semiconductor layer 1 is preferably from −60° C. to 50° C., more preferably 30° C. or less for improving flatness of the interface between an impurity implantation layer 9 and a source-drain region 6 as a silicon monocrystal.

### (Studies of Upper Limit Value and Lower Limit Value of Impurity Concentration)

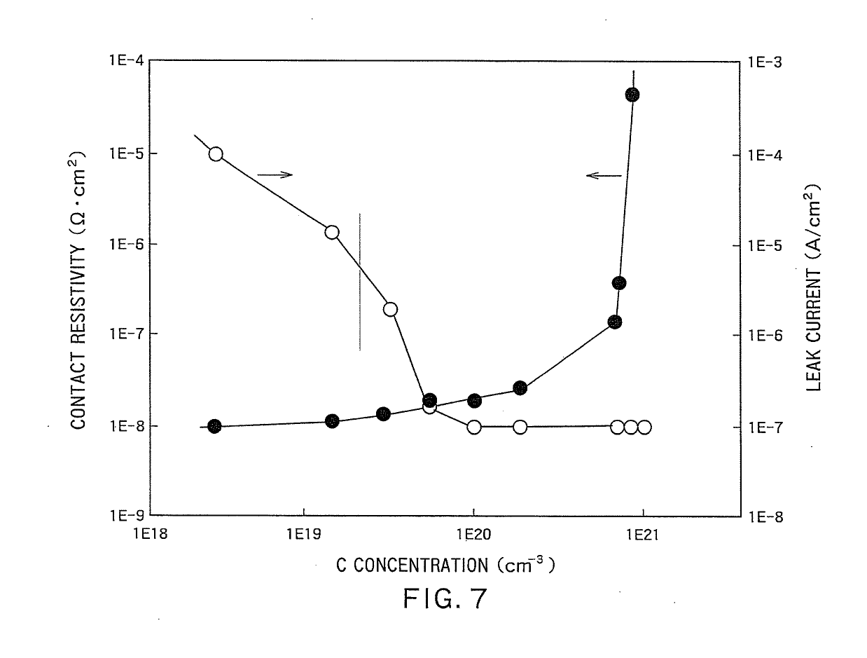

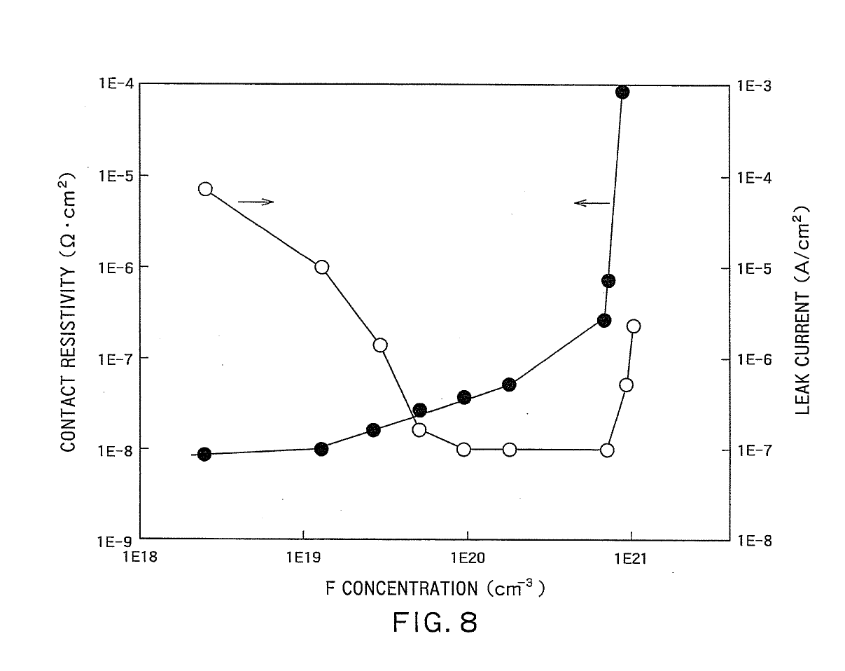

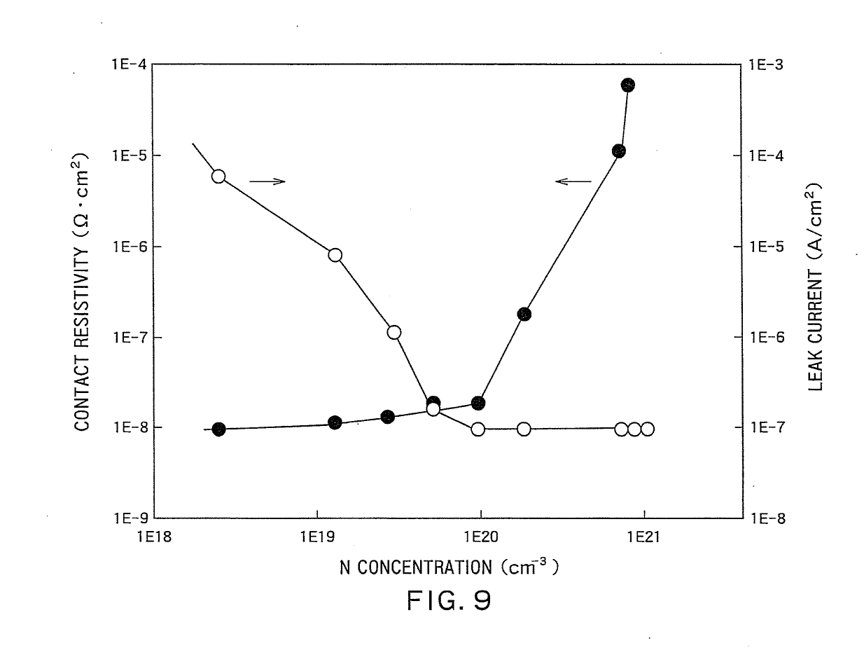

FIG. 7 is a graph of carbon concentration, contact resistivity and leak current. FIG. 8 is a graph of fluorine concentration, contact resistivity and leak current. FIG. 9 is a graph of nitrogen concentration, contact resistivity and leak current. In FIG. 7, the horizontal axis indicates C concentration (cm⁻³), the vertical axis on the space left side of FIG. 7 indicates contact resistivity (Ω·cm²), and the vertical axis on the space right side of FIG. 7 indicates leak current (A/cm²). The sign of a white circle shown in FIG. 7 denotes leak current with respect to C concentration, and the sign of a black circle denotes contact resistivity with respect to C concentration. In FIG. 8, the horizontal axis indicates F concentration (cm⁻³), the vertical axis on the space left side of FIG. 8 indicates contact resistivity (Ω·cm²), and the vertical axis on the space right side of FIG. 8 indicates leak current (A/cm²). The sign of a white circle shown in FIG. 8 denotes leak current with respect to F concentration, and the sign of a black circle denotes contact resistivity with respect to F concentration. In FIG. 9, the horizontal axis is N concentration (cm⁻³), the vertical axis on the space left side of FIG. 9 is contact resistivity (Ω·cm²), and the vertical axis on the space right side of FIG. 9 is leak current (A/cm²). The sign of a white circle shown in FIG. 9 denotes leak current with respect to N concentration, and the sign of a black circle denotes contact resistivity with respect to N concentration. The contact resistivity shown in FIGS. 7 to 9 is calculated in such a manner that an Si substrate is doped with conductive impurities so that surface concentration of the Si substrate becomes 2E15 cm⁻² or more, and subjected to heat treatment of activation, an Si oxide film is formed on the Si substrate, a Kelvin pattern having a contact opened with a contact diameter of 20 to 100 nm is formed in the Si oxide film, a W/TiN/Ti electrode and a wiring pattern are formed by using the Kelvin pattern, and TiSi₂ is formed on the interface with the Si substrate, and thereafter voltage is measured while passing a constant current of 50 to 500 μA to measure contact resistance value and multiply the value by contact area.

The upper limit value and the lower limit value of C concentration, F concentration and N concentration are hereinafter studied. In the case where the ion-implanted impurities are carbon, as shown in FIG. 7, when C concentration in silicon exceeds approximately 1E21 cm⁻³ (1×10²¹ cm⁻³), carbon as an interstitial atom increases and a crystal defect is formed so easily. Therefore, C concentration needs to be determined at less than approximately 1E21 cm⁻³ (1×10²¹ cm⁻³) for restraining contact resistance.

When C concentration in silicon becomes approximately 5E19 cm⁻³ (5×10¹⁹ cm⁻³), the diffusion inhibiting effect of phosphorus and boron becomes so small that a source region and a drain region short-circuit easily, for example, in a MOSFET (Metal-Oxide-Semiconductor Field-Effect Transistor) with a gate length of 30 nm or less; as a result, leak current becomes so large that desired performance is not obtained. Accordingly, it is desirable that C concentration is 5E19 cm⁻³ (5×10¹⁹ cm⁻³) or more and less than 1E21 cm⁻³ (1×10²¹ cm⁻³).

In the case where the ion-implanted impurities are fluorine, as shown in FIG. 8, when F concentration in silicon exceeds approximately 1E21 cm⁻³ (1×10²¹ cm⁻³), excessive fluorine terminates a dangling bond of silicon to form a crystal defect. Once a crystal defect is formed, boron and phosphorus gather there so easily that repeatability of impurity distribution is not obtained and the increase of pn junction leak current is brought. As shown in FIG. 8, contact resistance increases so abruptly at an F concentration of approximately 1E21 cm⁻³ (1×10²¹ cm⁻³) or more. Therefore, F concentration needs to be restrained to less than approximately 1E21 cm⁻³ (1×10²¹ cm⁻³).

Similarly to carbon, when F concentration becomes approximately 5E19 cm⁻³ (5×10¹⁹ cm⁻³), the diffusion inhibiting effect of phosphorus and boron becomes so small that a source region and a drain region short-circuit easily, for example, in a MOSFET with a gate length of 30 nm or less; as a result, leak current becomes so large that desired performance is not obtained. Accordingly, it is desirable that F concentration is 5E19 cm⁻³ (5×10¹⁹ cm⁻³) or more and less than 1E21 cm⁻³ (1×10²¹ cm⁻³).

In the case where the ion-implanted impurities are nitrogen, as shown in FIG. 9, when N concentration in silicon exceeds approximately 1E20 cm⁻³ (1×10²⁰ cm⁻³), the activation efficiency of p-type or n-type impurities lowers and contact resistance rises. Accordingly, it is desirable that N concentration is less than approximately 1E20 cm⁻³ (1×10²⁰ cm⁻³).

From the viewpoint of restraining p-type or n-type impurities from diffusing, N concentration needs to be approximately 5E19 cm⁻³ (5×10¹⁹ cm⁻³) or more in consideration of the above-mentioned concentration range. Accordingly, it is desirable that N concentration is 5E19 cm⁻³ (5×10¹⁹ cm⁻³) or more and less than 1E20 cm⁻³ (1×10²⁰ cm⁻³).

The above-mentioned modification allows the process time of producing p-type and n-type transistors to be shortened and allows the production cost of a semiconductor device to be restrained. P-type or n-type impurities may be restrained from diffusing and activated at so high concentration. Accordingly, contact resistance in forming an electrode is restrained from rising and an LSI production process with high yield becomes feasible.

The embodiments described above allow a crystal defect to be decreased while restraining implanted impurities from diffusing. Also, the embodiments described above allow an impurity diffusion layer to be formed at so low temperature as to be effective for producing a semiconductor device, in which heat treatment at high temperature is not preferable. Furthermore, the embodiments described above allow leak current to be reduced by reason of decreasing a crystal defect.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A producing method for a semiconductor device, comprising forming an impurity implantation layer by implanting into a semiconductor layer first impurities containing phosphorus or boron in a form of molecular ion and second impurities containing carbon, fluorine or nitrogen with less implantation amount than the phosphorus or boron in a form of molecular ion.

2. The producing method for a semiconductor device according to claim 1, wherein the first impurities contain Pa (where a is an integer of 2 or more).

3. The producing method for a semiconductor device according to claim 1, wherein the first impurities contain BbHc(where b is an integer of 2 or more, c is an integer of 6 or more).

4. The producing method for a semiconductor device according to claim 1, wherein the second impurities contain CdHe (where d is an integer of 2 or more, e is an integer of 6 or more).

5. The producing method for a semiconductor device according to claim 4, wherein the second impurities are implanted so that carbon concentration in the impurity implantation layer becomes 5×10¹⁹ cm⁻³ or more and less than 1×10²¹ cm⁻³.

6. The producing method for a semiconductor device according to claim 1, wherein the second impurities contain F₂ or PF₃.

7. The producing method for a semiconductor device according to claim 6, wherein the second impurities are implanted so that fluorine concentration in the impurity implantation layer becomes 5×10¹⁹ cm⁻³ or more and less than 1×10²¹ cm⁻³.

8. The producing method for a semiconductor device according to claim 1, wherein the second impurities contain N₂ or NH₃.

9. The producing method for a semiconductor device according to claim 8, wherein the second impurities are implanted so that nitrogen concentration in the impurity implantation layer becomes 5×10¹⁹ cm⁻³ or more and less than 1×10²⁰ cm⁻³.

10. The producing method for a semiconductor device according to claim 1, wherein an implantation of the first impurities and the second impurities is performed while cooling the semiconductor layer to 0° C. or less.

11. The producing method for a semiconductor device according to claim 1, wherein the second impurities are implanted before the first impurities are implanted.

12. The producing method for a semiconductor device according to claim 1, wherein an implantation of the first impurities and the second impurities is performed by using a plasma doping method.

13. The producing method for a semiconductor device according to claim 1, wherein after an implantation of the first impurities and the second impurities, heat treatment by an electromagnetic wave is performed in an inert gas atmosphere or an atmosphere including oxygen by 10% or less to activate the first impurities.

14. The producing method for a semiconductor device according to claim 1, wherein after an implantation of the first impurities and the second impurities, a microwave is irradiated to activate the first impurities.

15. The producing method for a semiconductor device according to claim 14, wherein the microwave has a frequency from 2.45 GHz to 50 GHz.

16. The producing method for a semiconductor device according to claim 14, characterized in that an irradiation of the microwave is performed so that a temperature of the semiconductor layer becomes 500° C. or less.

17. A producing method for a semiconductor device, comprising forming an impurity implantation layer by implanting into a semiconductor layer first impurities containing phosphorus or boron in a form of molecular ion and second impurities containing carbon with less implantation amount than the phosphorus or boron in a form of an atomic ion.

18. The producing method for a semiconductor device according to claim 17, wherein an implantation of the first impurities and the second impurities is performed while cooling the semiconductor layer to 0° C. or less.

19. The producing method for a semiconductor device according to claim 17, wherein after an implantation of the first impurities and the second impurities, heat treatment by an electromagnetic wave is performed in an inert gas atmosphere or an atmosphere including oxygen by 10% or less to activate the first impurities.

20. The producing method for a semiconductor device according to claim 17, wherein after an implantation of the first impurities and the second impurities, a microwave is irradiated to activate the first impurities.
